(19) United States
(12) Patent Application Publication
(10) Pub. No.: US 2026/0247735 A1
(43) Pub. Date: Aug. 20, 2026

(54) CAMERA MODULE

(71) Applicant: SAMSUNG ELECTRO-MECHANICS CO., LTD., Suwon-si (KR)

(72) Inventor: Heung Woo PARK, Suwon-si (KR)

(73) Assignee: SAMSUNG ELECTRO-MECHANICS CO., LTD., Suwon-si (KR)

(21) Appl. No.: 19/263,641

(22) Filed: Jul. 9, 2025

(30) Foreign Application Priority Data
Feb. 17, 2025 (KR) 10-2025-0019963

(51) Int. Cl. H10F 39/00

(52) U.S. Cl. CPC H10F 39/811; H10F 39/804; H10F 39/8063

(57) ABSTRACT

A camera module is provided. The camera module includes an upper housing comprising an upper wall and an upper side wall and in which at least one guide protrusion is disposed at a lower end portion of the upper side wall; a substrate disposed at a lower portion of the upper side wall, and a fastening groove is disposed in an edge region of the substrate; and an image sensor mounted on the substrate. The substrate includes a conductive pad disposed to adjoin the fastening groove, and the guide portion is inserted into the fastening groove. The substrate is fixed to the upper housing through a substrate fixing layer respectively coupled to the conductive pad and the guide protrusion.

### CROSS-REFERENCE TO RELATED APPLICATIONS

This application claims the benefit under 35 USC § 119(a) of Korean Patent Application No. 10-2025-0019963 filed on Feb. 17, 2025, in the Korean Intellectual Property Office, the entire disclosure of which is incorporated herein by reference for all purposes.

### BACKGROUND

### 1. Field

The following description relates to a camera module.

### 2. Description of Related Art

An effort has recently been made to reduce the size of components mounted in electronic devices due to a trend of miniaturization and slimming of the form factor of portable electronic devices including a mobile phone. Additionally, technologies that integrate operations of various electronic components are being implemented in electronic devices. Electronic components such as camera modules are implemented in smartphones, notebook computers, and vehicles, as only examples.

As video photographing increases, the implementation of camera modules in smartphone with good portability has increased. Additionally, the camera module is being used to implement a state-of-the-art advanced driver assistance system (ADAS) for an autonomous driving function in the vehicle.

It is desirous that the size of camera modules is decreased while the performance of the camera module is improved.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a camera module includes an upper housing comprising an upper wall and an upper side wall and in which at least one guide protrusion is disposed at a lower end portion of the upper side wall; a substrate disposed at a lower portion of the upper side wall, and a fastening groove disposed in an edge region of the substrate; and an image sensor mounted on the substrate, wherein the substrate comprises a conductive pad disposed to adjoin the fastening groove, wherein the guide protrusion is disposed in the fastening groove, and wherein the substrate is fixed to the upper housing through a substrate fixing layer that is respectively coupled to the conductive pad and the guide protrusion.

The substrate fixing layer may be configured to have conductivity.

The substrate may include a noise emitting wiring layer connected to the conductive pad.

The camera module may further include a connector connected to the substrate, wherein the noise emitting wiring layer may be connected to the connector.

A support portion and a protruding portion disposed at an outer circumference of the support portion may be disposed at the lower end portion of the upper side wall, and the guide protrusion may be disposed at the support portion.

The camera module may further include a lower housing connected to a lower portion of the upper housing and including an insertion portion that is inserted into the lower end portion of the upper side wall.

At least one region of the insertion portion may be inserted between the protruding portion and the guide protrusion.

The camera module may further include a housing bonding layer disposed in a region where the insertion portion and the lower end portion of the upper side wall are in contact with each other.

A connection pad may be disposed in at least one region of a side surface of the substrate.

The connection pad may be in contact with the housing bonding layer.

The connection pad may be configured to have conductivity.

The conductive pad may be disposed to surround the fastening groove.

Other features and aspects will be apparent from the following detailed description, the drawings, and the claims.

### BRIEF DESCRIPTION OF DRAWINGS

FIG. 1 illustrates a longitudinal cross-sectional view along one direction of an example camera module, in accordance with one or more embodiments.

FIG. 2 illustrates a longitudinal cross-sectional view along the other direction of the example camera module, in accordance with one or more embodiments.

FIG. 3 illustrates an enlarged view of a region A of FIG. 1.

FIG. 4 illustrates an enlarged view of a region B of FIG. 2.

FIG. 5 illustrates a bottom view of an upper housing in a state in which the upper housing is coupled to a substrate.

FIG. 6 illustrates a bottom view of the upper housing.

FIG. 7 illustrates a view of a first surface of the substrate.

FIG. 8 illustrates a view of a state in which the substrate is disposed in a fastening groove of the upper housing.

FIG. 9 illustrates a view of a first surface of a substrate, in accordance with one or more embodiments.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

One or more examples may provide a camera module that is easy to miniaturize.

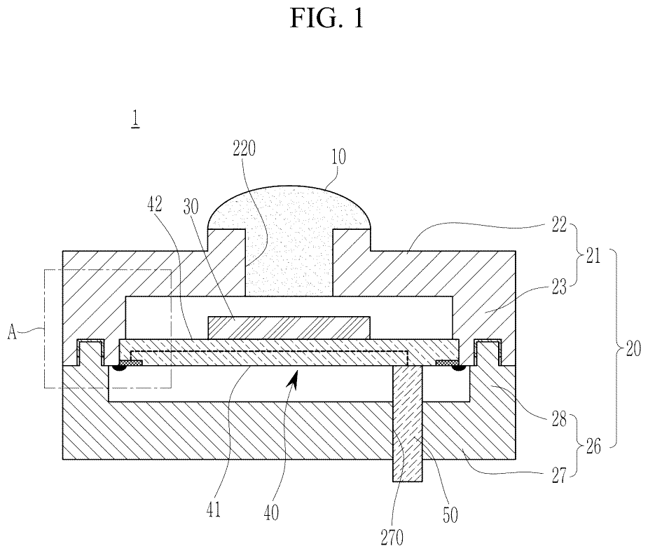

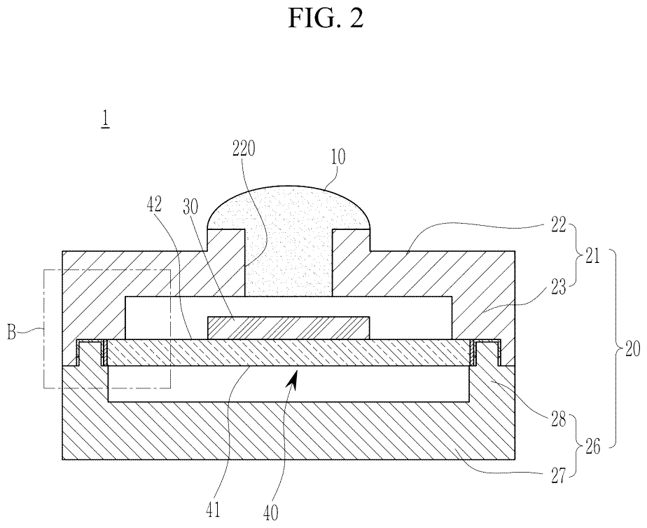

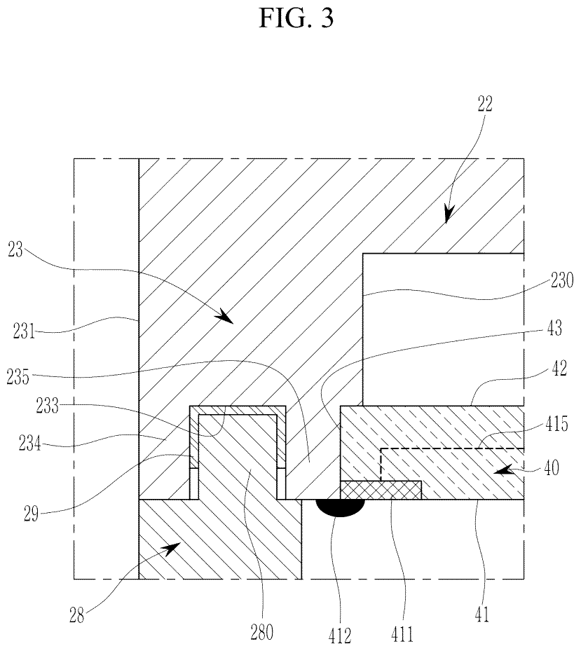

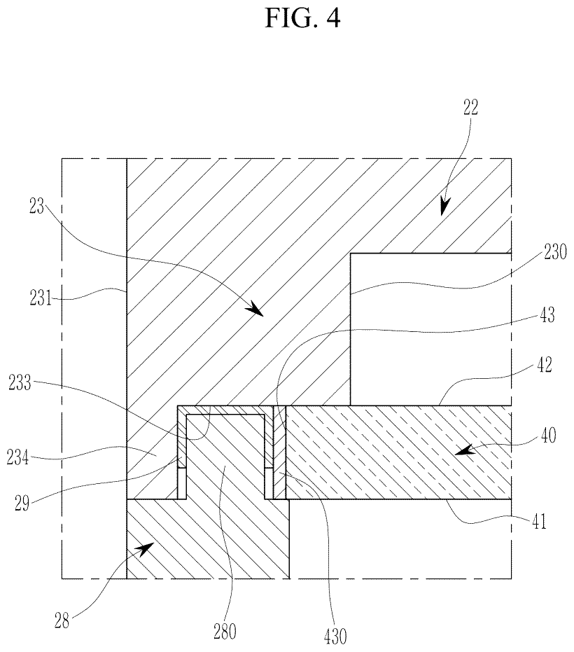

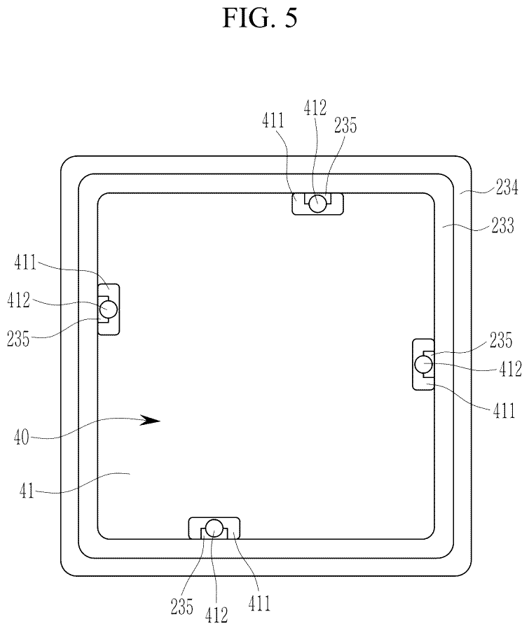

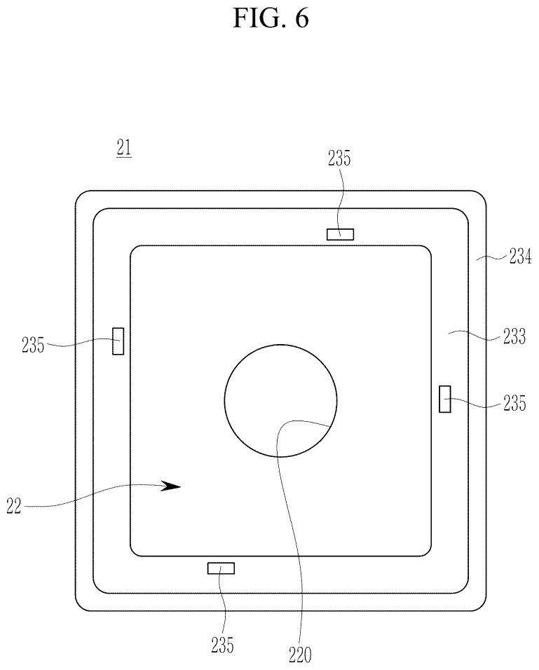

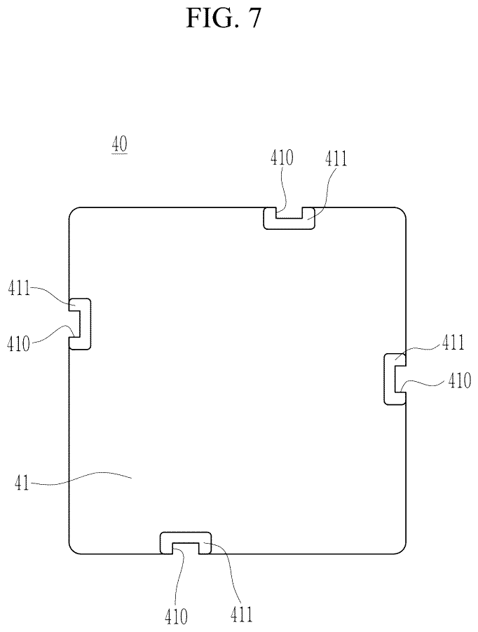

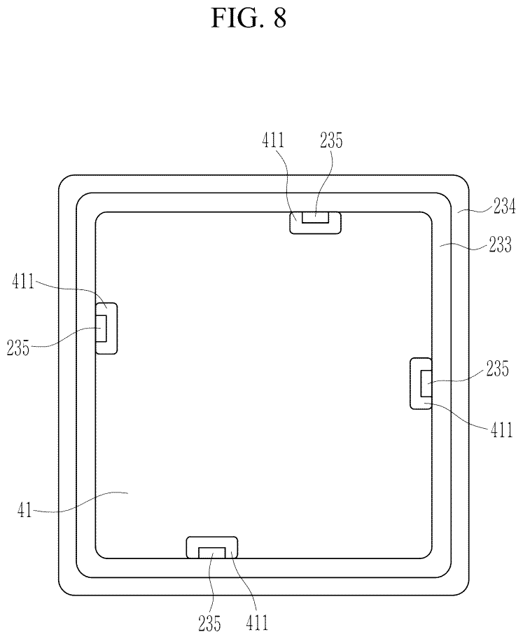

FIG. 1 illustrates a longitudinal cross-sectional view along one direction of an example camera module 1, in accordance with one or more embodiments, FIG. 2 illustrates a longitudinal cross-sectional view along the other direction of the camera module 1, in accordance with one or more embodiments, FIG. 3 illustrates an enlarged view of a region A of FIG. 1, FIG. 4 illustrates an enlarged view of a region B of FIG. 2, FIG. 5 illustrates a bottom view of an upper housing 21 in a state in which the upper housing 21 is coupled to a substrate (or a board) 40, FIG. 6 illustrates a bottom view of the upper housing 21, FIG. 7 illustrates a view showing a first surface 41 of the substrate 40, and FIG. 8 illustrates a view showing a state in which the substrate 40 is disposed in a fastening groove 410 of the upper housing 21.

FIG. 1 illustrates a longitudinal cross-sectional view across a region where a guide protrusion 235 described below is disposed, and FIG. 2 is a longitudinal cross-sectional view across a region where the guide protrusion 235 described below is not disposed.

Referring to FIGS. 1 to 8, the camera module 1, in accordance with one or more embodiments, may include a lens barrel 10, a housing 20, an image sensor 30, and the substrate 40.

The lens barrel 10 may accommodate at least one lens thereinside. The lens barrel 10 may have a cylindrical shape with a hollow space so that at least one lens for imaging a subject is accommodated thereinside. If a plurality of lenses are provided, the plurality of lenses may be installed at or in the lens barrel 10 along an optical axis. The plurality of lenses may be disposed as many times as necessary according to an implementation of the lens barrel 10, and may have the same or different optical characteristics such as a refractive index.

The housing 20 may have a box structure. The housing 20 may accommodate the substrate 40 with the image sensor 30 mounted thereinside. The housing 20 may support the lens barrel 10. The housing 20 may perform an operation of protecting an internal component of the camera module 1. Additionally, the housing 20 may perform an operation of shielding an electromagnetic wave. Accordingly, the housing 20 may block an external high frequency noise from penetrating into the housing 20.

The housing 20 may include an upper housing 21 and a lower housing 26.

The upper housing 21 may provide an upper structure of the housing 20. An opening 220 may be formed in the upper housing 21. The lens barrel 10 may be disposed to be inserted into the opening 220. The upper housing 21 may include an upper wall 22 and an upper side wall 23. The upper wall 22 of the upper housing 21 may become the upper wall 22 of the housing 20. The opening 220 may be disposed in the upper wall 22.

The upper side wall 23 may extend downward from an edge region of the upper wall 22.

Referring to FIG. 3, a support portion 233 and a protruding portion 234 may be disposed at a lower end portion of the upper side wall 23. The protruding portion 234 may be disposed at an outer circumference of the support portion 233 to be disposed to protrude downward from the support portion 233. If viewed from the bottom to the top, the protruding portion 234 may be formed in a ring structure. For example, if viewed from the bottom to the top, the protruding portion 234 may be formed in a quadrangular ring structure or the like. Additionally, if viewed from the bottom to the top, the protruding portion 234 may be provided so that a region where two surfaces meet is rounded.

At least one guide protrusion 235 may be disposed at a lower end portion of the upper side wall 23. The guide protrusion 235 may be disposed to protrude downward from the support portion 233. The guide protrusion 235 may be disposed to be spaced apart from an inner side surface 230 of the upper side wall 23 by a predetermined distance in a direction of an outer side surface 231 of the upper side wall 23. Accordingly, at least some regions of the support portion 233 may be disposed between the guide protrusion 235 and the inner side surface 230 of the upper side wall 23. For example, a plurality of guide protrusions 235 may be provided, and the plurality of guide protrusions 235 may be disposed to be spaced apart from each other. The guide protrusion 235 may be disposed to be spaced apart from the protruding portion 234.

The lower housing 26 may provide a lower structure of the housing 20. The lower housing 26 may be connected to a lower portion of the upper housing 21. The lower housing 26 may include a lower wall 27 and a lower side wall 28. The lower wall 27 of the lower housing 26 may become the lower wall 27 of the housing 20. A withdrawal hole 270 may be disposed in the lower wall 27. A connector 50 may be disposed in the withdrawal hole 270 so that one end of the connector 50 is disposed inside the housing 20 and the other end of the connector 50 is exposed to the outside of the housing 20.

The lower side wall 28 may extend upward from an edge region of the lower wall 27. An upper end portion of the lower side wall 28 may be coupled to a lower end portion of the upper side wall 23. For example, the upper end portion of the lower side wall 28 and the lower end portion of the upper side wall 23 may be coupled through a housing bonding layer 29. The lower side wall 28 and the upper side wall 23 may become a side wall of the housing 20 so that the upper side wall 23 becomes an upper portion of the side wall and the lower side wall 28 becomes a lower portion of the side wall. An insertion portion 280 may be disposed at the upper end portion of the lower side wall 28. The insertion portion 280 may be provided to protrude upward from an adjacent region thereof. If the lower housing 26 is connected to the upper housing 21, the insertion portion 280 may be inserted into the lower end portion of the upper side wall 23 of the upper housing 21.

At least one or some regions of the insertion portion 280 may be disposed in a region where the guide protrusion 235 is disposed in a state in which the upper housing 21 and the lower housing 26 are coupled. In this example, the insertion portion 280 may be disposed to face the support portion 233 of a region disposed between the protruding portion 234 and the guide protrusion 235 of the upper side wall 23. Accordingly, when the upper housing 21 and the lower housing 26 are coupled, at least some regions of the insertion portion 280 may be inserted between the protruding portion 234 and the guide protrusion 235.

Additionally, at least some regions of the insertion portion 280 may be disposed in a region without the guide protrusion 235 in a state where the upper housing 21 and the lower housing 26 are coupled. In this example, the insertion portion 280 may be disposed to face the support portion 233. The insertion portion 280 may be disposed to face the support portion 233 of a region spaced apart from the inner side surface 230 of the upper side wall 23 by a predetermined distance in a direction of the outer side surface 231 of the upper side wall 23. Accordingly, at least some regions of the support portion 233 may be disposed between the insertion portion 280 and the inner side surface 230 of the upper side wall 23. Additionally, the support portion 233 disposed between the insertion portion 280 and the inner side surface 230 of the upper side wall 23 may support the substrate 40.

If the insertion portion 280 is inserted into a lower end portion of the upper housing 21, the upper housing 21 and the lower housing 26 may be coupled to each other. The insertion portion 280 may be inserted to face the support portion 233 in a vertical direction in a region disposed inside the protruding portion 234. Additionally, the housing bonding layer 29 may be disposed in a region where the lower end portion of the upper side wall 23 and the upper end portion of the lower side wall 28 are in contact with each other to prevent the upper housing 21 and the lower housing 26 from being separated. The housing bonding layer 29 may be disposed in a region where the insertion portion 280 and the lower end portion of the upper side wall 23 are in contact with each other. For example, in a region with the guide protrusion 235, the housing bonding layer 29 may be disposed between the insertion portion 280 and the support portion 233, between the insertion portion 280 and the protruding portion 234, and between the insertion portion 280 and the guide protrusion 235.

Additionally, in a region without the guide protrusion 235, the housing bonding layer 29 may be disposed between the insertion portion 280 and a side surface 43 of the substrate 40. That is, the insertion portion 280 may be disposed to face the side surface 43 of the substrate 40, and the housing bonding layer 29 may be disposed between the insertion portion 280 and the side surface 43 of the substrate 40. The housing bonding layer 29 may be provided to have conductivity. For example, the housing bonding layer 29 may be formed through an adhesive. The adhesive may be provided to include a conductive material. That is, when the upper housing 21 and the lower housing 26 are bonded, the adhesive may be applied to the lower end portion of the upper side wall 23 or the upper end portion of the lower side wall 28, and the adhesive may be cured (or hardened) to form the housing bonding layer 29. The adhesive may be applied to a region where the insertion portion 280 is in contact with the lower end portion of the upper side wall 23. The adhesive may be cured to be disposed across a region where the insertion portion 280 and the lower end portion of the upper side wall meet.

Additionally, the housing bonding layer 29 may be formed through welding. That is, when the upper housing 21 and the lower housing 26 are bonded, welding may be performed in a region where the lower end portion of the upper side wall 23 and the upper end portion of the lower side wall 28 meet, so that the lower end portion of the upper side wall 23, the upper end portion of the lower side wall 28, or a portion of the lower end portion of the upper side wall 23 and a portion of the upper end portion of the lower side wall 28 may be melted and cured to form the housing bonding layer 29. Welding may be performed in a region where the insertion portion 280 is inserted into the lower end portion of the upper side wall 23. A portion of the upper housing 21 or the lower housing 26 that is melted and cured to form the housing bonding layer 29 may be provided to include a conductive material.

The image sensor 30 may be disposed at one side of the lens barrel 10 in an optical axis direction of the lens barrel 10. The image sensor 30 may convert light incident after passing through the lens into an electrical signal. As an example, the image sensor 30 may be a charge-coupled device (CCD), a complementary metal-oxide semiconductor (CMOS), as only examples. The image sensor 30 may be mounted on the substrate 40.

The image sensor 30 may be electrically connected to the substrate 40. For example, the image sensor 30 may be directly connected to the substrate 40 by wire bonding or the like. Both ends of a wire may be respectively adhered to a connection terminal of the image sensor 30 and a connection terminal of the substrate 40.

The substrate 40 may be a flexible printed circuit board (FPCB) or the like. For example, the substrate 40 may be one of a resin substrate such as polyimide having flexibility, a rigid flexible printed circuit board (RFPCB), and a two-layered FPCB. However, the one or more examples are not limited thereto.

The substrate 40 may be connected to an external circuit through the connector 50. For example, the connector 50 may be provided to penetrate the housing 20 so that one end of the connector 50 is connected to the substrate 40 and the other end of the connector 50 is exposed to the outside of the housing 20. Accordingly, if the other end of the connector 50 is connected to the external circuit, the substrate 40 may be connected to the external circuit through the connector 50.

Referring again to FIG. 3, the substrate 40 may include a first surface 41 and a second surface 42 disposed in opposite directions from each other, and a side surface 43 disposed between the first surface 41 and the second surface 42. If the substrate 40 is fixed to the housing 20, the first surface 41 of the substrate 40 may face downward (i.e., toward the lower wall 27 of the housing 20), and the second surface 42 of the substrate 40 may face upward (i.e., toward the upper wall 22 of the housing 20). Accordingly, the first surface 41 of the substrate 40 may be referred to as a lower surface of the substrate 40, and the second surface 42 of the substrate 40 may be referred to as an upper surface of the substrate 40.

At least one fastening groove 410 (FIG. 7) may be disposed in an edge region of the substrate 40. At least one fastening groove 410 may be disposed at an outer circumference of the substrate 40. If the substrate 40 is disposed at the lower end portion of the upper side wall 23 of the upper housing 21, the guide protrusion 235 may be inserted into the fastening groove 410. For example, in an assembly process of the camera module 1, the substrate 40 may be fixed to the upper housing 21, and then the upper housing 21 may be coupled to the lower housing 26. To this end, the substrate 40 may be inserted into the upper housing 21 to be disposed at the support portion 233 of the upper side wall 23. In the process, the guide protrusion 235 of the upper housing 21 may be disposed in the fastening groove 410 of the substrate 40 so that the substrate 40 is assembled at a correct position in the upper housing 21.

A conductive pad 411 may be disposed on the first surface 41 of the substrate 40. The conductive pad 411 may be made of a metal material or the like. The conductive pad 411 may be disposed at the edge region of the substrate 40. The conductive pad 411 may be disposed to be adjoined to the fastening groove 410 on the first surface 41. The conductive pad 411 may be disposed to surround the fastening groove 410 on the first surface 41. That is, the conductive pad 411 may be disposed in an edge region of the first surface 41 of the substrate 40, and at least one of fastening grooves 410 may be formed in a region where the conductive pad 411 is disposed. For example, the conductive pad 411 may be provided in the number corresponding to the number of fastening grooves so that the fastening groove 410 is formed in the region where the conductive pad 411 is disposed. However, the fastening groove 410 may also be formed in a region where there is no conductive pad 411. That is, some of the plurality of fastening grooves 410 may be formed in a region having the conductive pad 411, and the others of the plurality of fastening grooves 410 may be formed in a region without the conductive pad 411. Additionally, the fastening groove 410 may be formed in some of regions where the conductive pads 411 are each disposed, and the fastening groove 410 may not be formed in the others of the regions where the conductive pads 411 are each disposed. FIG. 7 illustrates an example in which four conductive pads 411 are provided and four fastening grooves 410 are formed in regions where the four conductive pads 411 are each disposed.

The substrate 40 may be fixed to the upper housing 21 through a substrate fixing layer 412. The substrate fixing layer 412 may be disposed across the conductive pad 411 and the guide protrusion 235 and may be respectively coupled to the conductive pad 411 and the guide protrusion 235 to fix the substrate 40 to the upper housing 21. For example, the substrate fixing layer 412 may be formed through an adhesive. That is, when the substrate 40 is fixed to the upper housing 21, the adhesive may be applied to a region adjacent to the substrate 40 and the upper housing 21, and the adhesive may be cured to form the substrate fixing layer 412. The adhesive may be applied across the conductive pad 411 and the guide protrusion 235. The substrate fixing layer 412 formed by curing the adhesive may be disposed across the conductive pad 411 and the guide protrusion 235 to fix the conductive pad 411 and the guide protrusion 235 to each other.

Additionally, the substrate fixing layer 412 may be formed through solder. That is, when the substrate 40 is fixed to the upper housing 21, soldering may be performed in a state in which the solder is disposed in a region adjacent to the substrate 40 and the upper housing 21, so that the solder forms the substrate fixing layer 412. Soldering may be performed in a state in which the solder is disposed across the conductive pad 411 and the guide protrusion 235. Accordingly, the substrate fixing layer 412 may be disposed across the conductive pad 411 and the guide protrusion 235 to fix the conductive pad 411 and the guide protrusion 235 to each other.

Additionally, the substrate fixing layer 412 may be formed through welding. That is, when the substrate 40 is fixed to the upper housing 21, welding may be performed in a region adjacent to the substrate 40 and the upper housing 21, so that the substrate 40, the upper housing 21, or a portion of the substrate 40 and a portion of the upper housing 21 may be melted and cured to form the substrate fixing layer 412. Welding may be performed in a region adjacent to the conductive pad 411 and the guide protrusion 235. Accordingly, the substrate fixing layer 412 may be formed by melting and curing the guide protrusion 235, the conductive pad 411, or the guide protrusion 235 and the conductive pad 411. Additionally, the substrate fixing layer 412 may be disposed across the conductive pad 411 and the guide protrusion 235 to fix the conductive pad 411 and the guide protrusion 235 to each other.

A noise emitting wiring layer 415 connecting the conductive pad 411 and the connector 50 may be disposed at the substrate 40. The noise emitting wiring layer 415 may allow a noise signal entering the conductive pad 411 to be transferred to the connector 50.

Referring to FIG. 4, a connection pad 430 may be disposed on at least some regions of the side surface 43 of the substrate 40. The connection pad 430 may have conductivity. For example, the connection pad 430 may be provided with a metal material or a similar material. If the substrate 40 is fixed to the upper housing 21 and the upper housing 21 is fixed to the lower housing 26, the connection pad 430 may be in contact with the housing bonding layer 29.

In the camera module 1, in accordance with one or more embodiments, the substrate 40 may be effectively fixed to the housing 20. In the camera module 1, in accordance with one or more embodiments, the substrate 40 may be fixed to the upper housing 21 through the substrate fixing layer 412. That is, the substrate 40 may be fixed to the upper housing 21 without a bolt or similar device. Accordingly, a region where the bolt or similar device is inserted in the substrate 40 may be omitted, so that the substrate 40 performing the same operation is manufactured in a smaller size. Additionally, as the substrate 40 is miniaturized, the camera module 1 may be miniaturized.

Additionally, the camera module 1, in accordance with one or more embodiments, may effectively block a high frequency noise. The housing 20 may be provided to include a material that blocks a high frequency noise introduced from the outside to the inside. In this example, if there is a path through which a high frequency noise absorbed by the housing 20 is emitted to the outside of the housing 20, the high frequency noise may be more effectively blocked from being introduced into the housing 20. In the camera module 1, in accordance with one or more embodiments, the upper housing 21 and the substrate 40 may be connected to each other through the substrate fixing layer 412. Additionally, the substrate fixing layer 412 may be connected to the connector 50 via the conductive pad 411 and the noise emitting wiring layer 415. Therefore, a high frequency noise entering the upper housing 21 may be transferred to the connector 50 through the conductive pad 411 and the noise emitting wiring layer 415. Additionally, if the connector 50 is connected to an external circuit, the high frequency noise transferred to the connector 50 may be transferred to a noise emitting path of the external circuit. Additionally, the substrate fixing layer 412 may have conductivity so that the high frequency noise is effectively transferred. For example, an adhesive used for forming the substrate fixing layer 412 may include a conductive material. Additionally, a solder used for forming the substrate fixing layer 412 may include a conductive material. Additionally, when the substrate fixing layer 412 is formed through welding, a material forming the substrate fixing layer 412 through melting and curing may include a conductive material.

Additionally, in the camera module 1, in accordance with one or more embodiments, a high frequency noise introduced into the lower housing 26 may be transferred to the upper housing 21, and then may be transferred through the above-described path. The high frequency noise of the lower housing 26 may be transferred to the upper housing 21 through the connection pad 430. Additionally, the housing bonding layer 29 may be provided to have conductivity so that the high frequency noise of the lower housing 26 is transferred to the upper housing 21 through the housing bonding layer 29. For example, an adhesive used to form the housing bonding layer 29 may include a conductive material. Additionally, when the housing bonding layer 29 is formed through welding, a material forming the substrate fixing layer 412 through melting and curing may include a conductive material.

Additionally, the camera module 1, in accordance with one or more embodiments, may have an improved sealing characteristic through the connection pad 430 disposed on the side surface 43 of the substrate 40.

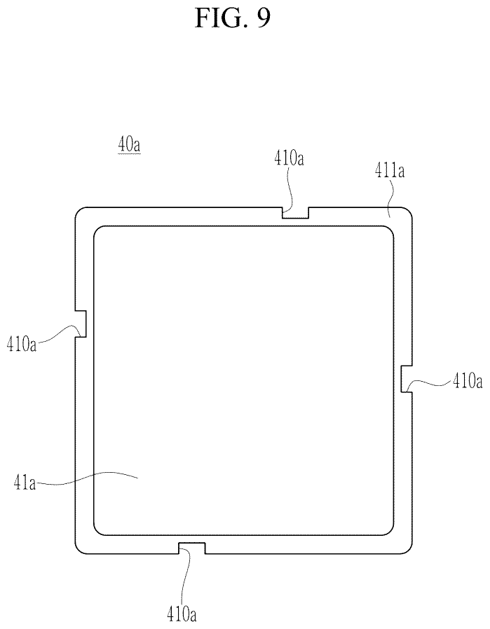

FIG. 9 illustrates a view of a first surface 41a of a substrate 40a according to another embodiment.

Referring to FIG. 9, at least one fastening groove 410a may be disposed at an outer circumference of the substrate 40a. A conductive pad 411a may be disposed on the first surface 41a of the substrate 40a. The conductive pad 411a may be disposed at an edge region of the substrate 40a. The conductive pad 411a may be provided as a ring structure along the edge region of the substrate 40a. The conductive pad 411a may be disposed to surround the fastening groove 410a on the first surface 41a.

Because another structure of the substrate 40a and a connection relationship between the substrate 40a and the housing 20 are the same, as or similar to, those described in FIGS. 1 to 8, a repeated description thereof will be omitted.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A camera module, comprising:
an upper housing comprising an upper wall and an upper side wall and in which at least one guide protrusion is disposed at a lower end portion of the upper side wall;
a substrate disposed at a lower portion of the upper side wall, and a fastening groove disposed in an edge region of the substrate; and
an image sensor mounted on the substrate,
wherein the substrate comprises a conductive pad disposed to adjoin the fastening groove,
wherein the guide protrusion is disposed in the fastening groove, and
wherein the substrate is fixed to the upper housing through a substrate fixing layer that is respectively coupled to the conductive pad and the guide protrusion.

2. The camera module of claim 1, wherein the substrate fixing layer is configured to have conductivity.

3. The camera module of claim 2, wherein the substrate comprises a noise emitting wiring layer connected to the conductive pad.

4. The camera module of claim 3, further comprising a connector connected to the substrate,
wherein the noise emitting wiring layer is connected to the connector.

5. The camera module of claim 1, wherein a support portion and a protruding portion disposed at an outer circumference of the support portion are disposed at the lower end portion of the upper side wall, and the guide protrusion is disposed at the support portion.

6. The camera module of claim 5, further comprising a lower housing connected to a lower portion of the upper housing and comprising an insertion portion that is inserted into the lower end portion of the upper side wall.

7. The camera module of claim 6, wherein at least one region of the insertion portion is inserted between the protruding portion and the guide protrusion.

8. The camera module of claim 6, further comprising a housing bonding layer disposed in a region where the insertion portion and the lower end portion of the upper side wall are in contact with each other.

9. The camera module of claim 8, wherein a connection pad is disposed in at least one region of a side surface of the substrate.

10. The camera module of claim 9, wherein the connection pad is in contact with the housing bonding layer.

11. The camera module of claim 9, wherein the connection pad is configured to have conductivity.

12. The camera module of claim 1, wherein the conductive pad is disposed to surround the fastening groove.
